(19) United States
(12) Patent Application Publication
(10) Pub. No.: US 2026/0026290 A1
(43) Pub. Date: Jan. 22, 2026

(54) BUFFER APPARATUS, PREPROCESSING APPARATUS MOUNTING APPARATUS, PREPROCESSING METHOD AND MOUNTING METHOD

(71) Applicant: SHIBAURA MECHATRONICS CORPORATION, Kanagawa (JP)

(72) Inventors: Toshifumi OKAWARA, Kanagawa (JP); Naoki SETO, Kanagawa (JP)

(21) Appl. No.: 19/344,619

(22) Filed: Sep. 30, 2025

Related U.S. Application Data
(63) Continuation of application No. PCT/JP2024/013207, filed on Mar. 29, 2024.

(30) Foreign Application Priority Data
Mar. 31, 2023 (JP) 2023-058750
Mar. 31, 2023 (JP) 2023-058752

(51) Int. Cl. H01L 21/67; H01L 21/52; H01L 21/683

(52) U.S. Cl. CPC H01L 21/67144; H01L 21/52; H01L 21/6836

(57) ABSTRACT

A buffer apparatus, a preprocessing apparatus, a mounting apparatus, a preprocessing method and a mounting method that can reduce bonding failure due to time elapsed from preprocessing of an electronic component and a mounting board to a bonding process. The buffer apparatus of the present embodiment includes a storage 161 that stores a component supply body TW that is a workpiece which is a wafer W diced into an electronic component E attached on a tape T attached to a ring R, and a mounting board BW that is a workpiece on which the electronic component E released from the component supply body TW is mounted after surface processing and/or a cleaning process; a chamber 162 that houses the storage 161; and a storage adjustment unit 163 that adjusts temperature, humidity, and pressure of gas inside the storage 161 independently from the chamber 162.

### CROSS-REFERENCE TO RELATED APPLICATION

This application is a Continuation of PCT Application No. PCT/JP2024/013207, filed on Mar. 29, 2024, and claims priority to Japanese Patent Application No. 2023-058750, filed on Mar. 31, 2023 and Japanese Patent Application No. 2023-058752, filed on Mar. 31, 2023, the entire contents of both of which are incorporated herein by reference.

### FIELD OF INVENTION

The present disclosure relates to a buffer apparatus, a preprocessing apparatus, a mounting apparatus, a preprocessing method and a mounting method.

### BACKGROUND

One method to mount electronic components such as semiconductor chips on mounting boards is direct bonding. The direct bonding is a method to directly adhere and bond each connection terminal of the mounting board and the electronic component by solid-phase bonding without using bonding material (adhesive) such as soldering bumps. An apparatus for performing bonding to adhere the electronic component and the mounting board as such is a bonding apparatus. The direct bonding eliminates the need to consider the effect of the bonding material, and achieves narrow spacing between the connection terminals and highly dense packages.

To directly bond the electronic component on the mounting board, preprocessing is performed on the electronic component and the mounting board in advance. In the pre-processing, surface processing such as an activation process and a purification process, and a cleaning process are performed. The activation process is a process to activate surfaces of the electronic component and the mounting board using active species such as ions and radicals generated by turning reaction gas into plasma. The activation refers to the breaking of chemical bonds of molecules on the surface. Furthermore, the purification is a process to clean the surface of the electronic component and the mounting board using the generated activated species such as ions and radicals, etc. The purification refers to the removal of particles attached to the surface by bouncing them or the removal of organic substances by degrading them. The cleaning process is a process to clean particles and others remaining on the surface of the electronic component and the mounting board.

### SUMMARY OF INVENTION

### Problems to be Solved by Invention

The condition of the surface of the electronic component and the mounting board that has undergone the above preprocessing may change such as by gradual deactivation over time and organic substances attaching on the surface. By this, bonding strength when bonding may be reduced. Insufficient bonding strength means bonding failure, leading to product failure.

Furthermore, in the bonding process to adhere the electronic component and the mounting board by a bonding apparatus, when mounting a plurality of the electronic components on one mounting board, the supply timing of the electronic components and the mounting board to the bonding apparatus may not match. The electronic component and the mounting board are different in terms of the preparation time until they are ready to be carried into the bonding apparatus after the activation process and the purification process. Accordingly, the difference in processing timing and a number of processes (a number of mountings) in the bonding process (mounting process) of the electronic component and the mounting board produces difference in the surface condition during bonding, increasing the possibility of deactivation of either of the electronic component and the mounting board or attachment of organic substances to either of the electronic component and the mounting board.

The objective of the embodiment of the present disclosure is to provide a buffer apparatus, a preprocessing apparatus, a mounting apparatus, a preprocessing method and a mounting method that can reduce the bonding failure due to the time elapsed from the preprocessing of the electronic component and the mounting board to the bonding process.

### Means to Solve the Problem

A buffer apparatus of the embodiment includes: a storage that stores, after surface processing and/or cleaning process, a component supply body that is a workpiece which is a wafer diced into an electronic component attached on a tape attached to a ring, and a mounting board that is a workpiece on which the electronic component is mounted; a chamber that houses the storage; and a storage adjustment unit that adjusts temperature, humidity, and pressure of gas inside the storage independently from the chamber.

A preprocessing apparatus of the embodiment comprising: a surface processing unit that processes a surface of the component supply body which is the wafer diced into the electronic component attached on the tape attached to the ring and/or the surface of a mounting board on which the electronic component is mounted; a supply body cleaning unit that cleans the component supply body; a mounting board cleaning unit that cleans the mounting board; and the buffer apparatus.

A mounting apparatus of the embodiment includes: a surface processing unit that processes a surface of a component supply body which is a wafer diced into an electronic component attached on a tape attached to a ring and/or a surface of a mounting board on which the electronic component is mounted; a supply body cleaning unit that cleans the component supply body; a mounting board cleaning unit that cleans the mounting board; the buffer apparatus; a bonding unit that mounts the electronic component on the mounting board; a transportation unit that transports the component supply body and the mounting board; and a preprocessing control unit that controls any of the surface processing unit, the supply body cleaning unit, and the mounting board cleaning unit to again clean or process the surface of the component supply body or the mounting board when predefined time has elapsed after the component supply body or the mounting board were housed in the buffer apparatus.

A preprocessing method of the embodiment comprising a surface processing process of processing a surface of a component supply body which is a wafer diced into an electronic component attached on a tape attached to a ring and/or a surface of a mounting board on which the electronic component is mounted using a surface processing unit; a supply body cleaning process of cleaning the component supply body using a supply body cleaning unit; a mounting board cleaning process of cleaning the mounting board using a mounting board cleaning unit; a supply body housing process of temporarily housing the component supply body in a storage provided in a chamber using a buffer apparatus for the component supply body, gas inside the storage being controlled independently from the chamber; and a mounting board housing process of temporarily housing the mounting board in a storage provided in a chamber using a buffer apparatus for the mounting board, gas inside the storage being controlled independently from the chamber; wherein: in the supply body housing process, the surface processing process and/or the supply body cleaning process are performed again when predefined time elapses since the component supply body is housed, and in the mounting board housing process, the surface processing process and/or the mounting board cleaning process are performed again when predefined time elapses since the mounting board is housed.

A mounting method of the embodiment includes: a surface processing process of processing a surface of a component supply body which is a wafer diced into an electronic component attached on a tape attached to a ring and/or a surface of a mounting board on which the electronic component is mounted using a surface processing unit; a supply body cleaning process of cleaning the component supply body using a supply body cleaning unit; a mounting board cleaning process of cleaning the mounting board using a mounting board cleaning unit; a supply body housing process of temporarily housing the component supply body in a storage provided in a chamber using a buffer apparatus for the component supply body, gas inside the storage being controlled independently from the chamber; a mounting board housing process of temporarily housing the mounting board in a storage provided in a chamber using a buffer apparatus for the mounting board, gas inside the storage being controlled independently from the chamber; and a bonding process of releasing the electronic component from the component supply body and mounting the electronic component on the mounting board using a bonding unit; wherein: in the supply body housing process, the surface processing process and/or the supply body cleaning process are performed again when predefined time elapses since the component supply body is housed, and in the mounting board housing process, the surface processing process and/or the mounting board cleaning process are performed again when predefined time elapses since the mounting board is housed.

### Effect of Invention

The embodiment of the present disclosure can reduce the bonding failure due to the time elapsed from the preprocessing of the electronic component and the mounting board to the bonding process.

### BRIEF DESCRIPTION OF DRAWINGS

FIG. 1 is an explanation diagram illustrating processes of the mounting apparatus according to the embodiment.

FIG. 2 is a simplified perspective plan view illustrating the configuration of the mounting apparatus according to the embodiment.

FIG. 3 is a simplified configuration diagram illustrating the supply body cleaning unit and mounting board cleaning unit of the mounting apparatus.

FIG. 4 is a simplified configuration diagram illustrating the supply body buffer unit and the mounting board buffer unit of the mounting apparatus.

FIG. 5 is a block diagram illustrating the control unit.

FIG. 6 is a flowchart illustrating the operation procedures according to the embodiment.

FIG. 7 is a flowchart illustrating the procedure from housing the workpiece in the supply body buffer unit and the mounting board buffer unit to carrying out the workpiece.

FIG. 8 is a simplified perspective plan view illustrating the example in which the storage for the component supply body and the storage for the mounting board are provided in the common chamber.

FIG. 9 is a modified example of FIG. 8 and is a simplified perspective plan view illustrating the example in which the placement unit for the component supply body and the placement unit for the mounting board are provided in the chamber.

FIG. 10 is a simplified perspective plan view illustrating the modified example in which the storage is common for the component supply body and the mounting board.

FIG. 11 is a modified example of FIG. 10 and is a simplified perspective plan view illustrating the example in which the placement unit for the component supply body and the placement unit for the mounting board are provided in the chamber.

### EMBODIMENTS

Hereinafter, embodiments of the present disclosure will be described referring to the figures. Note that the figures are schematic and include portions with exaggerated size and ratio to ease the understanding thereof.

### SUMMARY

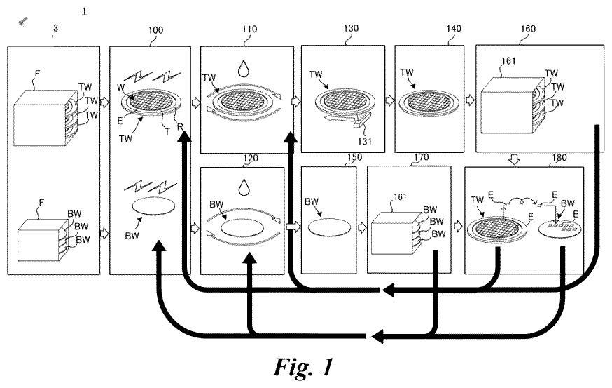

In the present embodiment, as illustrated in FIG. 1, processing is performed to a component supply body TW and a mounting board BW. The component supply body TW is a wafer (semiconductor wafer) attached on a tape T attached to a ring R. Here, the wafer W is diced into electronic components E. The tape T is a stretchable sheet with an adhesive surface, and the adhesive strength can be reduced by irradiation of UV (ultraviolet) light. The mounting board BW is a wafer (semiconductor wafer) on which the electronic component E released from the component supply body TW is bonded (mounted). Note that, since the processing target is the electronic component E, in the following description, processing to the component supply body TW means processing to the electronic component E. Furthermore, when the component supply body TW and the mounting board BW are not distinguished from each other, they are just called a workpiece.

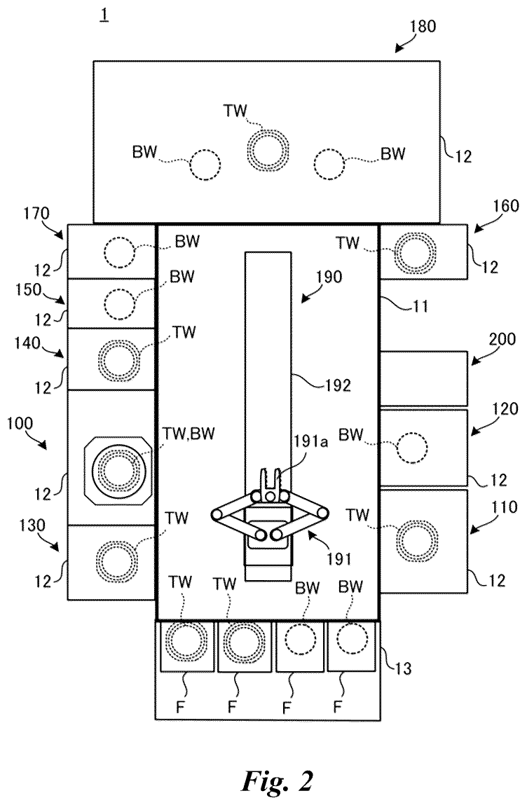

As illustrated in FIG. 2, a mounting apparatus 1 of the present embodiment is an apparatus that performs preprocessing (activation process, purification process, and cleaning process) to each of the component supply bodies TW and the mounting boards BW, which are housed in a transportation container F such as FOUP (Front Opening Unified Pod) and FOSB (Front Opening Shipping Box) and supplied, one piece at a time, to mount the electronic component E.

The mounting apparatus 1 is configured by arranging a plurality of chambers 12, which house devices for various processing, around a base 11 that is a box-shaped container. A load port 13 to load the transportation container F is provided to the base 11. The transportation container F housing the unprocessed component supply body TW and mounting board BW is loaded on the load port 13, and the component supply body TW and the mounting board BW are taken out one by one from this transportation container using a transportation unit 190, and are carried into each chamber 12, processed, and carried out from each chamber 12. Furthermore, an unillustrated FFU (Fan Filter Unit) is provided to a ceiling of the base 11, and the FFU generates down flow of clean air to maintain a clean atmosphere in the base 11. Such an FFU is also provided to the chamber 12 if necessary.

The mounting apparatus 1 of the present embodiment includes a preprocessing apparatus that performs preprocessing of the electronic component E including an activation process, a purification process, and a cleaning process, a buffer apparatus that temporarily houses the component supply body TW and the mounting board BW, and a bonding apparatus that crimps the electronic component on the mounting board BW.

In detail, the mounting apparatus 1 of the present embodiment is an apparatus including a surface processing unit 100, a supply body cleaning unit 110, a mounting board cleaning unit 120, an adjustment processing unit 130, a positioning unit 140, an alignment unit 150, a supply body buffer unit 160, a mounting board buffer unit 170, a bonding unit 180, a transportation unit 190, and a control unit 200.

The preprocessing apparatus is configured by the surface processing unit 100, the supply body cleaning unit 110, the mounting board cleaning unit 120, the positioning unit 140, and the alignment unit 150. The buffer apparatus is configured by the supply body buffer unit 160 and the mounting board buffer unit 170. The bonding apparatus is configured by the bonding unit 180. A transportation apparatus that is the transportation unit 190 is configured to transport the workpiece between each apparatus. Also, the control unit 200 controls each device, so that the mounting apparatus 1 is configured.

### [Surface Processing Unit]

The surface processing unit 100 is a processing room to perform surface processing to the surface of the component supply body TW and the mounting board BW. The surface processing is processing to modify (activate, purify) the bonding surface of the component supply body TW and the mounting board BW. Furthermore, such modification makes them hydrophilic. The surface processing unit 100 of the present embodiment has a plasma generator that makes reaction gas introduced inside the vacuum chamber into plasma, and modifies the bonding surfaces of the component supply body TW and the mounting board BW by irradiating generated ions.

### (Supply Body Cleaning Unit)

The supply body cleaning unit 110 is a processing room to clean the component supply body TW. The supply body cleaning unit 110 removes particles remaining on the plasma-processed component supply body TW or particles produced due to the plasma processing by cleaning. Furthermore, the cleaning target is the surface of the electronic component E, between the electronic components E, and the adhesive surface of the tape T, and particles attached thereto are removed by cleaning. The presence of particles affects the bonding strength (reduces the bonding strength). Therefore, by cleaning the bonding surface, the reduction of the bonding strength can be suppressed.

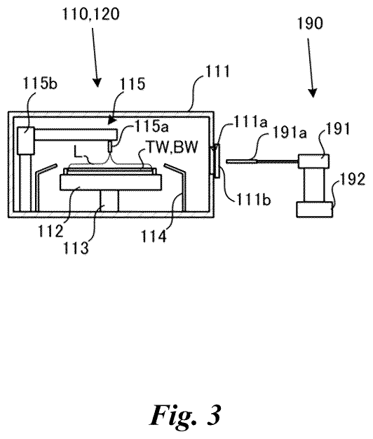

As illustrated in FIG. 3, the supply body cleaning unit 110 includes a cleaning room 111 that is a container to perform a cleaning process therein, a support 112 that supports the component supply body TW, a rotation mechanism 113 that rotates the support 112, a cup 114 that receives cleaning liquid L splashed from around the component supply body TW, and a supplying unit 115 that supplies the cleaning liquid L. A nozzle 115a that drops the cleaning liquid L and a moving mechanism 115b that moves the nozzle 115a are provided to the supplying unit 115.

The cleaning liquid L is supplied from the nozzle 115a to the surface to be processed of the component supply body TW supported by the support 112 and rotated by the rotation mechanism 113 to perform the cleaning process. For example, DIW is used for the cleaning liquid L. An opening 111a to carry the component supply body TW in and out is provided to the cleaning room 111, and the opening 111a is configured to be opened and closed by a shutter 111b.

Note that, although not illustrated, the rotation mechanism 113 of the supply body cleaning unit 110 includes an expansion unit that stretches (expands) the tape T in the supply body cleaning unit 110 supported by the support 112, widens spacing between the electronic components E, and cleans particles between the spacing.

### [Mounting Board Cleaning Unit]

The mounting board cleaning unit 120 is a processing room to clean the mounting board BW. The mounting board cleaning unit 120 removes particles remaining on the plasma-processed mounting board BW or particles produced due to the plasma processing by cleaning. The presence of particles affects the bonding strength (reduces the bonding strength). Therefore, by cleaning the bonding surface, the reduction of the bonding strength can be suppressed. Similarly to the supply body cleaning unit 110 illustrated in FIG. 3, the mounting board cleaning unit 120 includes a cleaning room 111 that is a container to perform a cleaning process therein, a support 112 that supports mounting board BW, a rotation mechanism 113 that rotates the support 112, a cup 114 that receives cleaning liquid L splashed from surrounding of the mounting board BW, and a supplying unit 115 that supplies the cleaning liquid L.

### [Adjustment Processing Unit]

The adjustment processing unit 130 adjusts the adhesive strength of the tape T to decrease by irradiating UV light to the tape T of the component supply body TW after cleaning. As illustrated in FIG. 1, the adjustment processing unit 130 includes an irradiation apparatus 131 that irradiates UV light to the entire lower portion of the housed component supply body TW by scanning a UV light source.

### [Positioning Unit]

The positioning unit 140 positions the component supply body TW. The positioning unit 140 is a contact-type centering device that adjusts a center of the component supply body TW to match a reference position provided inside the positioning unit 140 by contacting an outer periphery of the component supply body TW.

### [Alignment Unit]

The alignment unit 150 aligns the mounting board BW. The alignment unit 150 is non-contact-type (optical type) centering device that adjusts a center of the mounting board BW to match a reference position provided inside the alignment unit 150.

### [Supply Body Buffer Unit]

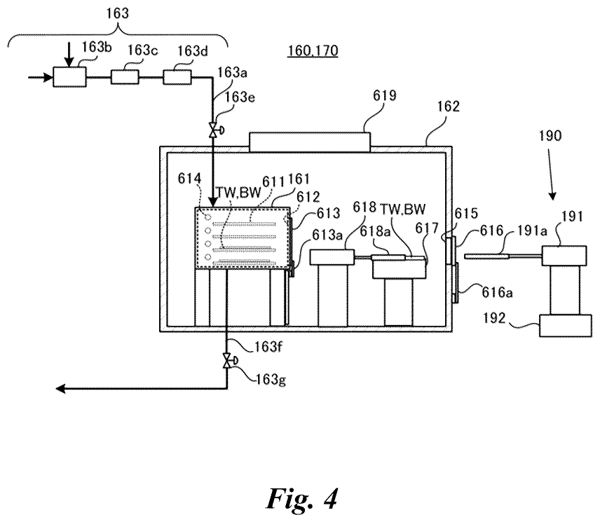

The supply body buffer unit 160 is a buffer apparatus that temporarily houses the component supply body TW. The supply body buffer unit 160 houses the component supply body TW before being carried into the bonding unit 180. Note that the supply body buffer unit 160 may store the component supply body TW in which some of the electronic component E has been released by bonding. As illustrated in FIG. 4, the supply body buffer unit 160 includes a storage 161, a chamber 162 (12), and a storage adjustment unit 163. The storage 161 is a container that stores the component supply body TW after cleaning by the supply body cleaning unit 110. The chamber 162 is one of the chambers 12 forming the mounting apparatus 1 and is a container that houses the storage 161. The storage adjustment unit 163 controls temperature, humidity, and pressure inside the storage 161 independently from the chamber 162. Independently control means control without gas flowing to each other.

### (Storage)

The storage 161 has a box-shape and can house a plurality of the component supply bodies TW stacked with spacing therebetween. The storage 161 includes a support 611, an opening 612, a storage-side shutter 613, and an irradiation device 614.

The support 611 is a shelf that supports the component supply body TW. A plurality of the supports 611 is provided stepwise inside the storage 161 so that each supports the component supply bodies TW one by one.

The opening 612 is a hole for carrying the component supply body TW in and out and is provided to one side of the storage 161. The storage-side shutter 613 has a size that can cover the opening 612 and is provided to the side of the storage 161 where the opening 612 is provided so as to be movable between a close position to close the opening 612 and an open position to open the opening 612.

The storage-side shutter 613 is a door that is positioned at the open position when carrying the component supply body TW into or out from the storage 161 and is positioned at the close position when carrying the component supply body TW into or out from the chamber 162. The storage-side shutter 613 is driven by a cylinder and is connected to an opening/closing mechanism 613a that slides along a guide member.

The irradiation device 614 is a device that irradiates UV light to the component supply body TW. For example, the irradiation device 614 is an excimer UV lamp. Light source of the irradiation device 614 is arranged at the side opposite the opening 612 via the support 611 inside the storage 161 at height and angle that enable irradiation of light to the component supply body TW on the support 611.

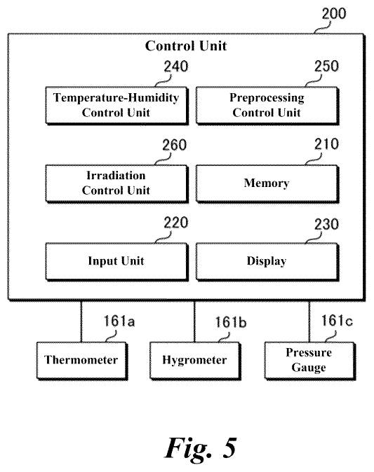

Furthermore, a thermometer 161a that detects the temperature of gas inside the storage 161, a hygrometer 161b that detects the humidity inside the storage 161, and a pressure gauge that detects the pressure inside the storage 161 are provided in the storage 161 (refer FIG. 5). The thermometer 161a, the hygrometer 161b, and the pressure gauge 161c are connected to the control unit 200 described later.

### (Chamber)

The chamber 162 is a box with the size that can house the storage 161 therein. The chamber 162 includes an opening 615, a chamber-side shutter 616, a placement portion 617, a robot 618, and a blowing device 619.

The opening 615 is a hole for carrying the component supply body TW in and out and is provided to one side of chamber 162. The chamber-side shutter 616 has a size that can cover the opening 615 and is provided to the side of the chamber 161 where the opening 615 is provided so as to be movable between a close position to close the opening 615 and an open position to open the opening 615.

The chamber-side shutter 616 is a door that is positioned at the open position when carrying the component supply body TW into or out from the chamber 162 and is positioned at the close position when carrying the component supply body TW into or out from the storage 161. The chamber-side shutter 616 is driven by a cylinder and is connected to an opening/closing mechanism 616a that slides along a guide member.

The placement portion 617 is provided between the opening 615 and the storage 161 inside the chamber 162 and is a platform to place the component supply body TW carried in from the opening 615 thereon. The robot 618 includes a robot hand 618a that supports the component supply body TW and is a transportation device that transports the component supply body TW between the placement portion 617 and the storage 161. That is, the robot 618 carries the component supply body TW placed on the placement portion 617 into and out from the storage 161. Note that, the transportation device is not limited to the robot 618 and may be any configuration if the component supply body TW placed on the placement portion 617 can be carried into and out from the storage 161.

The blowing device 619 is an apparatus that generates down flow of cleaning gas in the chamber 162. The blowing device 619 is a FFU (Fan Filter Unit) with a ULPA filter (Ultra Low Penetration Air Filter). An unillustrated exhaustion port is provided at a position near a bottom of the chamber 162 and exhausts the cleaning gas outside the chamber 162 so as not to disturb the down flow. Or, a ventilation pipe to circulate the cleaning gas to the unillustrated FFU is provided.

### (Storage Adjustment Unit)

The storage adjustment unit 163 includes an air supply path 163a, a gas supply device 163b, a flow meter 163c, a filter 163d, a valve 163e, a exhaustion path 163f, and a valve 163g. The air supply path 163a is a ventilation path that is connected to an upper portion of the storage 161 and is drawn out of the chamber 162 without communicating with the chamber 162. The gas supply device 163b is an apparatus that supplies gas inside the storage via the air supply path 163a, In the present embodiment, the gas supply device is a bubbling device that supplies gas which is pre-heated N2 that is humidified by passing through water.

The flow meter 163c is a device that measures the flow rate of gas in the air supply path 163a. The filter 163d is a device that purifies gas in the air supply path 163a. The valve 163e is a flow rate adjustment valve that adjusts opening and closing of the air supply path 163a and the flow rate of gas in the air supply path 163a.

The exhaustion path 163f is a ventilation path that is connected to a lower portion of the storage 161 and is drawn out of the chamber 162 without communicating with the chamber 162. The valve 163g is a flow rate adjustment valve that adjusts opening and closing of the exhaustion path 163f and the flow rate of gas in the exhaustion path 163f.

### [Mounting Board Buffer Unit]

The mounting board buffer unit 170 is a buffer apparatus that temporarily houses the mounting board BW before being carried into the bonding unit 180. The mounting board buffer unit 170 houses the mounting board BW before being carried into the bonding unit 180. Note that mounting board buffer unit 170 may store the mounting board BW on which the electronic component E is mounted by bonding. As illustrated in FIG. 4, the mounting board buffer unit 170 includes a storage 161, a chamber 162 (12), and a storage adjustment unit 163, like the above supply body buffer unit 160. That is, the mounting board buffer unit 170 has the same configuration as the supply body buffer unit 160, except that the target that would be carried in the chamber 162 and housed in the storage is the mounting board BW.

### [Bonding Unit]

The bonding unit 180 is a processing room to remove the electronic component E on the component supply body TW and load the electronic component E on the mounting board BW. Although not illustrated, the bonding unit 180 includes a supply mechanism, a pickup mechanism, and a loading mechanism, and picks up the electronic component E on the component supply body TW carried in the supply mechanism by the pickup mechanism, delivers the electronic component E to the loading mechanism, and loads the electronic component E on the mounting board BW carried in the loading mechanism. Note that, as illustrated in FIG. 1, the bonding unit 180 in the present embodiment reverses the picked-up electronic component E, and mount the preprocessed surface on the preprocessed mounting board BW.

### [Transportation Unit]

The transportation unit 190 transports the component supply body TW and the mounting board BW between the load port 13 and each chamber 12 and between each chamber 12. As illustrated in FIGS. 2, the transportation unit 190 includes a transportation robot 191 and a moving mechanism 192. The transportation robot 191 is a double-arm type and includes a pair of robot hands 191a. Each of the pair of the robot hands 191a can respectively support the component supply body TW and the mounting board BW. The moving mechanism 192 moves and positions the transportation robot 191 to the load port 13 and each chamber 12. The robot hand 191a carries in and out the component supply body TW and the mounting board BW relative to each transportation container F and each chamber 12.

### (Control Unit)

The control unit 200 is a computer that controls each units of the mounting apparatus 1. The control unit 200 includes a processor that executes programs, a memory that stores various information such as programs and operation condition, and a driving circuit that drives each component. That is, the control unit 200 controls the surface processing unit 100, the supply body cleaning unit 110, the mounting board cleaning unit 120, the adjustment processing unit 130, the positioning unit 140, the alignment unit 150, the supply body buffer unit 160, the mounting board buffer unit 170, the bonding unit 180, and the transportation unit 190. As illustrated in FIG. 5, the control unit 200 includes a memory 210 that stores information, an input unit 220 to input the information, and a display unit 230 that displays the information,

Furthermore, as illustrated in FIG. 5, the control unit 200 of the present embodiment includes a temperature-humidity control unit 240 that controls the temperature and humidity inside the storage 161. The temperature-humidity control unit 240 adjusts the temperature, humidity, and pressure inside the storage to be the temperature, humidity, and pressure that can maintain the active state of the mounting board BW and the electronic component E on the component supply body TW housed in the storage 161 by controlling the storage adjustment unit 163 based on the temperature measured by the thermometer 161a, the humidity measured by the hygrometer 161b, and the pressure measured by the pressure gauge 161c. The range of the temperature, humidity, and pressure that can maintain the active state is determined by experiments and others beforehand, and is input by the input unit 220 and is stored in the memory 210.

Furthermore, the control unit 200 includes a preprocessing control unit 250 and an irradiation control unit 260. The preprocessing control unit 250 controls the surface processing unit 100, the supply body cleaning unit 110, or the mounting board cleaning unit 120 to perform cleaning and surface processing again when predefined time has elapsed after the component supply body TW or the mounting board BW is housed in the buffer apparatus (supply body buffer unit 160, the mounting board buffer unit 170). That is, the active state of the bonding surface of the electronic component E and the mounting board BW may gradually deactivate or organic substances may attach on the electronic component E and the mounting board BW when long time elapses without mounting after preprocessing by cleaning and surface processing is performed. Therefore, the preprocessing control unit 250 measures elapsed time after housing and performs preprocessing again when predefined time elapses. This time is time the active state of the bonding surface is maintained in the acceptable range. When the electronic component E is mounted on the mounting board BW within this time, the bonding strength will be in the acceptable range, however, after this time, the bonding strength will be outside the acceptable range. That is, the required bonding strength cannot be obtained. Note that the set time is obtained by experiments, etc. Such set time is input by the input unit 220 beforehand and is stored in the memory 210.

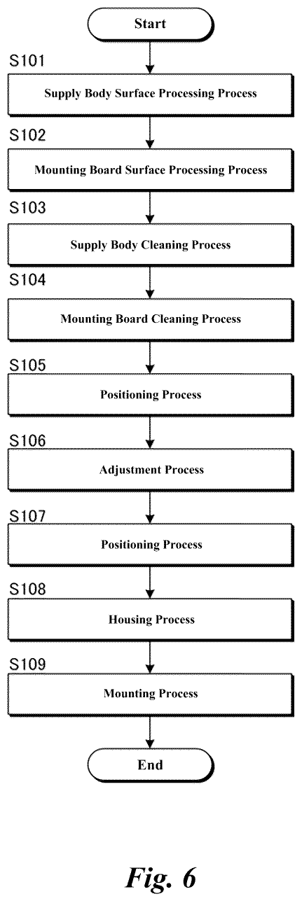

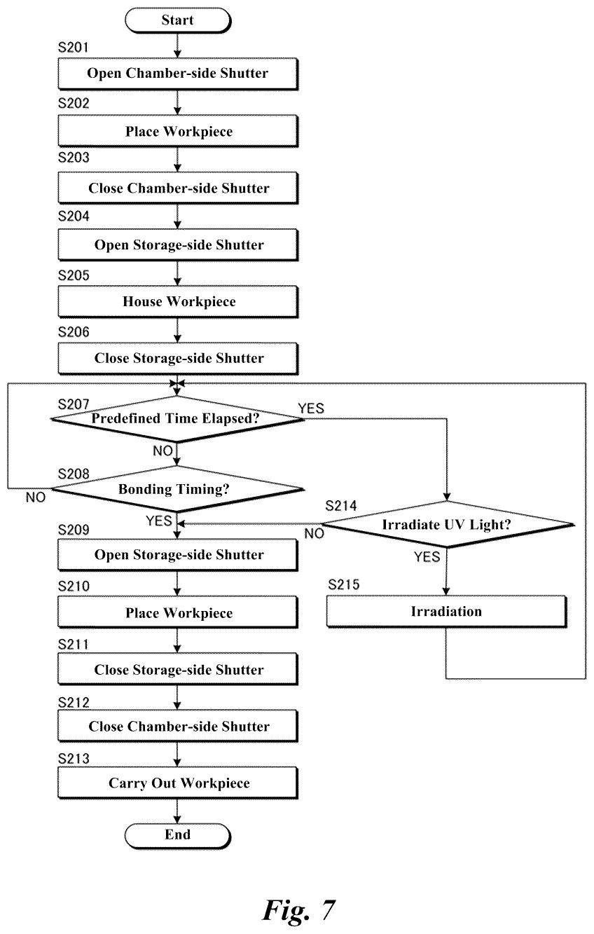

The irradiation control unit 260 controls the irradiation device 614 to irradiate UV light on the component supply body TW and the mounting board BW when the predefined time has elapsed, instead of performing preprocessing again. Whether to carry out the component supply body TW and the mounting board BW from the storage 161 and perform preprocessing again or to irradiate UV light while housing the component supply body TW and the mounting board BW in the storage 161 is determined according to the condition and types of the workpiece. For example, when some of the electronic components E on the component supply body TW is released for mounting or other electronic components E remain, large area of the tape T is exposed and the remaining electronic components E may be contaminated if cleaning is performed. Therefore, preprocessing is not performed again, and UV light is irradiated. Furthermore, when there is possibility that the electronic component E mounted on the mounting board BW is released due to transportation and cleaning of the mounting board BW, preprocessing is not performed again, and UV light is irradiated. Whether to irradiate UV light or not is input by the input unit 220 beforehand and is stored in the memory 210.

[Action] The action of the mounting apparatus 1 of the above present embodiment is described referring to the flowchart of FIGS. 6 and 7, in addition to the above FIGS. 1 to 5. A mounting method to mount the electronic component E on the mounting board BW by the following scheme is also an aspect of the present embodiment. Note that the following description is according to the flowchart of FIG. 6, however, each process includes cases in which they are performed concurrently.

As illustrated in FIG. 2, the transportation container F housing the component supply body TW and the transportation container F housing the mounting board BW is loaded on the load port 13. As illustrated in FIG. 4, down flow is generated inside the chambers 162 of the supply body buffer unit 160 and the mounting board buffer unit 170 by the blowing device 619. Furthermore, N2 gas is supplied in the storage 161 from the gas supply device 163b of the storage adjustment unit 163. The supply amount and exhaustion amount of the N₂ gas is adjusted by the valves 163e and 163g to maintain the predefined temperature, humidity, and pressure.

As illustrated in FIGS. 1 and 2, the transportation robot 191 receives the component supply body TW from the transportation container F on the load port 13, transports the component supply body TW to the surface processing unit 100, and activates and purifies the surface of the electronic component E by plasma processing (supply body surface processing process: step S101). Note that the transportation robot 191 receives the mounting board BW from the transportation container F during the surface processing of the component supply body TW. The transportation robot 191 receives the component supply body TW with the processed surface from the surface processing unit 100. In the surface processing unit 100m the surface of the mounting board BW is activated and purified by plasma processing (mounting board surface processing process: step S102).

The transportation robot 101 delivers the component supply body TW with the processed surface to the support 112 of the supply body cleaning unit 110. The supply body cleaning unit 110 cleans the component supply body TW by supplying the cleaning liquid L while rotating the component supply body TW by the support 112 and the rotation mechanism 113 (supply body cleaning process: step 103). Note that the tape T of the component supply body TW is expanded by the expansion unit, and the component supply body TW is cleaned in a state in which spacing between the electronic components E is expanded. After the cleaning by supplying the cleaning liquid L, the rotation mechanism 113 rotates the component supply body TW at high speed to shake off the cleaning liquid L for drying, and then the expansion unit releases the tape T so that the tape T contracts to the original state, restoring the spacing between the electronic components E. Note that, when the cleaning liquid L is water, hydroxyl group may be added to the surface of the component supply body TW.

After the surface processing of the mounting board BW in the surface processing unit 100 is completed, the transportation robot 101 receives the mounting board BW from the surface processing unit 100 and delivers the mounting board BW to the mounting board cleaning unit 120. The mounting board cleaning unit 120 cleans the mounting board BW by supplying the cleaning liquid L while rotating the mounting board BW (mounting board cleaning process: step 104). The mounting board BW is cleaned by supplying the cleaning liquid L, and then is rotated at high speed to shake of the cleaning liquid L for drying. This mounting board cleaning process may be performed concurrently with the supply body cleaning process. That is, the time for cleaning the component supply body TW and the time for cleaning the mounting board BW overlap. Note that, when the cleaning liquid L is water, hydroxyl group may be added to the surface of the mounting board BW.

After the cleaning process of the component supply body TW, the transportation robot 191 receives the component supply body TW from the supply body cleaning unit 110 and delivers the component supply body TW to the positioning unit 140. The positioning unit 140 positions the component supply body TW (positioning process: step S105). After the positioning, the transportation robot 191 receives the component supply body TW from the positioning unit 140 and delivers the component supply body TW to the adjustment processing unit 130. The adjustment processing unit 130 performs adjustment to reduce the adhesive strength of the tape T by irradiating UV light to the component supply body TW. Such positioning process and adjustment process overlap the mounting board cleaning process.

After the cleaning process of the mounting board BW, the transportation robot 191 receives the mounting board BW from the mounting board cleaning unit 120 and delivers the mounting board BW to the alignment unit 150. The alignment unit 150 aligns the mounting board BW (alignment process: step S107).

After the adjustment process of the component supply body TW, the transportation robot 191 receives the component supply body TW from adjustment processing unit 130 and delivers the component supply body TW to the supply body buffer unit 160. After the positioning of the mounting board BW is completed, the transportation robot 191 receives the mounting board BW from the alignment unit 150 and delivers the mounting board BW to the mounting board buffer unit 170.

After the component supply body TW and the mounting board BW are housed in the supply body buffer unit 160 and the mounting board buffer unit 170 (housing process: step S108), when the bonding unit 180 ready to accept, the transportation robot 191 receives the component supply body TW and the mounting board BW and delivers the component supply body TW and the mounting board BW to the bonding unit 180. That is, in response to a signal indicating the bonding unit 180 is ready to accept, the transportation robot 191 takes out the component supply body TW and the mounting board BW from the supply body buffer unit 160 and the mounting board buffer unit 170 and carries in the component supply body TW and the mounting board BW to the bonding unit 180.

Note that, as described later, after the surface processing and/or the cleaning, if the bonding unit 180 is not performing any processing or is in the state of processing completion, the component supply body TW and the mounting board BW may be directly provided to the bonding unit 180 without going through the supply body buffer unit 160 and the mounting board buffer unit 170.

The housing of the component supply body TW to the supply body buffer unit 160, the housing of the mounting board BW to the mounting board buffer unit 170, and the transportation thereafter is described by referring to the flowchart of FIG. 7. Here, the component supply body TW and the mounting board BW are not distinguished and are described as the workpiece. Firstly, the chamber-side shutter 616 opens while the storage-side shutter 613 is closed (step S201), and the transportation robot 191 places the workpiece on the placement portion 617 (step S202).

The chamber-side shutter 616 closes (step S203), the storage-side shutter 613 is opens (step S204), and the robot 618 houses the workpiece on the placement portion 617 so that the workpiece is supported by the support 611 inside the storage 161 (step S205). The storage-side shutter 613 closes (step and S206), and pressure sequentially, the temperature, humidity, inside the storage 161 is adjusted.

Furthermore, if the predefined time has not elapsed (step S207, NO) but the timing to carry in the workpiece to the bonding unit 180 comes (step S208, YES), the workpiece is carried out. That is, the storage-side shutter 613 opens while the chamber-side shutter 616 is closed (step S209), and the robot 618 places the workpiece on the placement portion 617 (step S210). The storage-side shutter 613 closes (step S211), the chamber-side shutter 616 opens (step S212), and the transportation robot 191 carries out the workpiece from the placement portion 617 (step S213).

When the predefined time has elapsed (step S207, YES) and it is not set to irradiate UV light in the storage 161 (step S214, NO), after the workpiece is carried out in steps S209 to S213, the surface processing, cleaning process, and adjustment process are performed again according to each workpiece (component supply body TW and mounting board BW). When it is set to irradiate UV light in the storage 161 (step S214, YES), the irradiation device 614 irradiates UV light on the workpiece (step S215).

Returning to the flowchart of FIG. 6, the transportation robot 191 delivers the component supply body TW and the mounting board BW to the bonding unit 180. In the bonding unit 180, the electronic component E is picked up from the component supply body TW and is loaded on the mounting board BW (mounting process: step S109).

During mounting, the transportation robot 191 receives next component supply body TW and the mounting board BW from the transportation container F of the load port 13, and performs the same process as above to the second workpiece. After the mounting of the first workpiece is completed, while each process for the second workpiece, the transportation robot 191 receives the component supply body TW and the mounting board BW from the bonding unit 180 and delivers the component supply body TW and the mounting board BW to the transportation container F of the load port 13.

Each action as described above is repeated to mount the electronic component E on the mounting board BW, and when supply of component supply body TW and/or the mounting board BW is finished, the mounting process is finished.

Note that, after the electronic component E on the component supply body TW is mounted on the mounting board BW, different electronic component E may be further bonded to an unmounted area of the mounting board BW, or the same electronic component E or the different electronic component E may be bonded to be stacked on the electronic component E that has already been mounted.

When using different electronic components E as such, the component supply body TW may be replaced with the component supply body TW with the different electronic components E while the electronic components E are still remaining on the component supply body TW. Time has elapsed from the surface processing and cleaning for the replaced component supply body TW, and further time elapses until it is used again. Therefore, the surface processing and cleaning may be performed again, if necessary.

In the present embodiment, the range of the temperature, humidity, and pressure that can maintain the active state is stored in the memory 210. The stored range of the temperature, humidity, and pressure may be the optimal value for each of the component supply body TW and the mounting board BW. Therefore, the optimal storage environment can be achieved by the supply body buffer unit 160 and the mounting board buffer unit 170. Of course, the applied temperature, humidity, and pressure may be common values.

Although it is described that the mounting apparatus 1 of the present embodiment includes the preprocessing apparatus that performs preprocessing of the electronic component E including the activation process, the purification process, and the cleaning process, the buffer apparatus that temporarily houses the component supply body TW and the mounting board BW, and the bonding apparatus that crimps the electronic component E on the mounting board BW, the preprocessing apparatus and the buffer apparatus are not necessarily integrated and included in the mounting apparatus 1.

The mounting apparatus 1 of the present embodiment may include a mounting apparatus in which the preprocessing apparatus, the buffer apparatus, and the bonding apparatus are installed and integrated on one base 11 and a mounting apparatus in which the preprocessing apparatus, the buffer apparatus, and the bonding apparatus are configured as independent apparatuses and the workpiece is transported by the independent transportation apparatus. In this case, the control unit 200 may be included in each apparatus, or one control unit 200 may control each apparatus, or the control unit 200 that integrates and controls the control units for each apparatus may be provided.

### Effect

(1) The buffer apparatus (the supply body buffer unit 160, the mounting board buffer unit 170) of the present embodiment includes: the storage 161 that stores the component supply body TW that is the workpiece which is the wafer W diced into the electronic component E attached on the tape T attached to the ring R, and the mounting board BW that is the workpiece on which the electronic component E is mounted after surface processing and/or cleaning process; the chamber 162 that houses the storage 161; and the storage adjustment unit 163 that adjusts temperature, humidity, and pressure of gas inside the storage 161 independently from the chamber 162.

Furthermore, the mounting apparatus 1 of the present embodiment includes: the surface processing unit 100 that processes the surface of the component supply body TW which is a wafer diced into the electronic component E attached on the tape T attached to the ring R and/or the surface of the mounting board BW on which the electronic component E is mounted; the supply body cleaning unit 110 that cleans the component supply body TW; the mounting board cleaning unit 120 that cleans the mounting board BW; the buffer apparatus; the bonding unit 180 that mounts the electronic component E on the mounting board BW; the transportation unit 190 that transports the component supply body TW and the mounting board BW; and the preprocessing control unit 250 that controls any of the surface processing unit 100, the supply body cleaning unit 110, and the mounting board cleaning unit 120 to again clean or process the surface of the component supply body TW or the mounting board BW when predefined time has elapsed after the component supply body TW or the mounting board BW were housed in the buffer apparatus.

The mounting method of the present embodiment includes: the surface processing process of processing the surface of the component supply body TW which is a wafer diced into the electronic component E attached on the tape T attached to the ring R and/or the surface of the mounting board BW on which the electronic component E is mounted using the surface processing unit 100; the supply body cleaning process of cleaning the component supply body TW using the supply body cleaning unit 110; the mounting board cleaning process of cleaning the mounting board BW using the mounting board cleaning unit 120; the supply body housing process of temporarily housing the component supply body TW in the storage 161 provided in the chamber 162 using the buffer apparatus for the component supply body TW (the supply body buffer unit 160), gas inside the storage 161 being controlled independently from the chamber 162; the mounting board housing process of temporarily housing the mounting board BW in the storage 161 provided in the chamber 162 using the buffer apparatus for the mounting board BW (the mounting board buffer unit 170), gas inside the storage 161 being controlled independently from the chamber 162; and the bonding process of releasing the electronic component E from the component supply body TW and mounting the electronic component E on the mounting board BW using the bonding unit 180.

Furthermore, in the mounting method, in the supply body housing process, the surface processing process and/or the supply body cleaning process are performed again when predefined time elapses since the component supply body TW is housed, and in the mounting board housing process, the surface processing process and/or the mounting board cleaning process are performed again when predefined time elapses since the mounting board BW is housed.

Accordingly, even if there is waiting time after the preprocessing until the bonding, the workpiece is kept inside the storage 161 with the temperature, humidity, and pressure adjusted to maintain the active state and clean state, so that the active state and clean state of the workpiece are maintained, enabling excellent bonding. By this, the bonding failure due to the time elapsed from the cleaning of the workpiece to the mounting of the electronic component E can be reduced.

The storage 161 is arranged inside the chamber 162, and the carrying in and out of the workpiece relative to the storage 161 is performed via the chamber 162. By this, the interior of the storage 161 does not directly contact the exterior of the storage 161, so that the change in the environment inside the storage 161 can be made small. The active state and purified state of the bonding surface of the workpiece housed in the storage 161 can be maintained, enabling excellent bonding. By this, the bonding failure due to the time elapsed from the cleaning of the workpiece to the mounting of the electronic component E can be reduced.

Furthermore, the pressure inside the chamber 162 and the storage 161 can be adjusted independently. By this, the outside gas is prevented from flowing into the chamber 162 by making the pressure inside the chamber 162 higher than the pressure outside the chamber 162, and the gas inside the chamber 162 is prevented from flowing into the storage 161 by making the pressure inside the storage 161 higher than the pressure inside the chamber 162. By this, the change in the environment inside the storage 161 can be surely made small.

The pressure inside the chamber 162 and the pressure inside the storage 161 is not limited to the above and may be the same as the air pressure inside the storage 161 and the air pressure inside the chamber 162 to suppress the outflow of the gas inside the storage 161 and the inflow of the gas inside the chamber 162 to the storage 161, enabling to make the change in the environment inside the storage 161 small.

Accordingly, since the workpiece can be housed inside the storage with the small change in the environment by the adjustment of the pressure inside the chamber 162 and the pressure inside the storage 161, the active state and purified state of the bonding surface can be maintained, enabling excellent bonding. By this, the bonding failure due to the time elapsed from the cleaning of the workpiece to the mounting of the electronic component E can be reduced.

Furthermore, since gas that is the environment, such as nitrogen (N2) can be supplied only in the storage 161, the usage amount of the gas such as nitrogen can be minimized. By this, the reduction of the running cost, and the improvement of the performance of the environment inside the storage 161 to maintain the active state and purified state of the bonding surface of the workpiece can be achieved. Furthermore, gas same as that in the storage 161 may be supplied also to the chamber 162 to make the environment condition inside the chamber 162 as same as the environment of the storage 161. By this, the environment inside the storage 161 can be more strictly maintained when carrying the workpiece in and out. Note that the environment condition here means the condition determined such as by types of the gas, components, component ratio, pressure, temperature, and humidity, etc. However, in the case of the same environment, not all of the items need to be the same, and a condition in which one or some of the items are the same is included.

(2) The blowing device 619 that generates down flow of cleaning gas in the chamber 162 is provided to the chamber 162. Therefore, the purified level of the workpiece can be maintained even from when the workpiece is carried into the chamber until the workpiece is housed in the storage 161.

(3) The openings 615 and 612 for carrying the workpiece in and out are provided to each of the chamber 162 and the storage 161, the chamber-side shutter 616 that opens when carrying the workpiece into and out from the chamber 162 and closes when carrying the workpiece into and out from the storage 161 is provided to the opening 615 of the chamber 162, and the storage-side shutter 613 that opens when carrying the workpiece into and out from the storage 161 and closes when carrying the workpiece into and out from the chamber 162 is provided to the opening 612 of the storage 161.

Therefore, when carrying the workpiece in and out, the gas outside the chamber 162 is prevented from flowing into the storage 161, so that the change in the environment condition inside the storage 161 can be made small. That is, by using double doors and controlling the timing to open each of the doors so that the doors will not open at the same time, the change in the environment condition inside the storage 161 when carrying the workpiece in and out can be minimized. In detail, when carrying the workpiece into and out from the chamber 162, it is preferable to close the opening 615 of the chamber 162 and wait until the environment inside the chamber 162 becomes the same as the environment inside the storage 161 and then open the opening 612 of the storage 161. By this, the environment inside the storage 161 can be strictly maintained.

(4) The chamber 162 includes the placement portion 617 to place the workpiece carried into the chamber 162, and the robot 618 that is the transportation device that carries the workpiece placed on the placement portion 617 into and out from the storage 161. Therefore, the transportation of the workpiece can be automated while maintaining the purified level inside the storage 161.

(5) The irradiation device 614 that irradiates UV light to the workpiece is provided in the storage 161. By this, the surface of the workpiece can be activated and purified. Furthermore, the irradiation device 614 may re-activate, re-purify, or maintain the active state and purified state of the workpiece that is returned from the bonding unit 180 and housed again. Furthermore, even if the workpiece is in the state unsuitable for performing preprocessing such as surface processing and cleaning by plasma, the workpiece may be activated and purified again. Furthermore, since the irradiation can replace the process to return and process the workpiece to the surface processing unit 100, the supply body cleaning unit 110, and the mounting board cleaning unit 120, said re-processing can be reduced, preventing the decrease in the processing efficiency.

### Modified Example

(1) In the processing process of the mounting apparatus 1, it is not necessary to temporarily house the workpiece in the buffer unit (the supply body buffer unit 160, the mounting board buffer unit 170) before bonding. If the bonding unit 180 can accept the workpiece, the workpiece may be directly carried in the bonding unit 180 without via the buffer unit. In this case, since the workpiece is immediately applied to the mounting process with the surface in the required active state and purified state, the effect on the mounting strength is small and the operation efficiency can be increased without the time housing the workpiece in the buffer unit, which is unnecessary.

Furthermore, if the bonding unit 180 cannot accept the workpiece but the waiting time calculated from the processing status of the bonding unit 180 is within the predefined threshold time, the workpiece may wait without being housed in the buffer unit. This threshold time may be time the surface of the workpiece can maintain the necessary active state and purified state and can be obtained in advance such as by experiments.

Furthermore, the time required for the mounting process is completed after the workpiece is carried into the bonding unit 180 is calculated, and if said time is within the threshold time that can maintain the necessary active state and purified state, the workpiece is carried into the bonding unit 180 without being housed in the buffer unit. At this time, if there is waiting time, this waiting time may be considered.

That is, when carrying in the workpiece to the bonding unit 180 and there is waiting time due to the processing status of the bonding unit 180, whether to house the workpiece in the buffer unit or not can be determined depending on the waiting time. By this, the operation efficiency can be increased without the time housing the workpiece in the buffer unit, which is unnecessary. Furthermore, the necessary housing to the buffer unit can be surely performed, and the mounting strength required for the mounting can be ensured.

Of course, the workpiece may be immediately housed in the buffer unit when it is determined that there is waiting time. As described above, whether to house the workpiece depending on the waiting time or to immediately house the workpiece can be selected.

(2) In the irradiation device 614, the light source may be provided to be movable, so that the irradiation device 614 can uniformly irradiate the entire workpiece by running light along the surface of each workpiece.

(3) The preprocessing control unit 250 may perform surface and processing cleaning again as appropriate depending on whether to prioritize the active state and purified state of the surface or the hydroxylated state after cleaning based on both elapsed time after surface processing and after cleaning. Furthermore, only cleaning process may be performed without performing surface processing again. Accordingly, various processing may be selected to perform various processing according to the property of the surface of the workpiece. By this, more products can be applied to the processing.

During the mounting in the bonding unit 180, the preprocessing control unit 250 can perform surface processing and cleaning again without transporting the component supply body TW and the mounting board BW to the bonding unit 180 when it can be determined that the predefined time has elapsed.

(4) Dedicated transportation units 190 may be provided to perform surface processing and cleaning again. Furthermore, the dedicated transportation unit 190 may be provided for each of the component supply body TW and the mounting board BW. By this, the transportation process for performing surface processing and cleaning again concurrently with the normal transportation unit 190, achieving the mounting apparatus 1 with high productivity by concurrent processes.

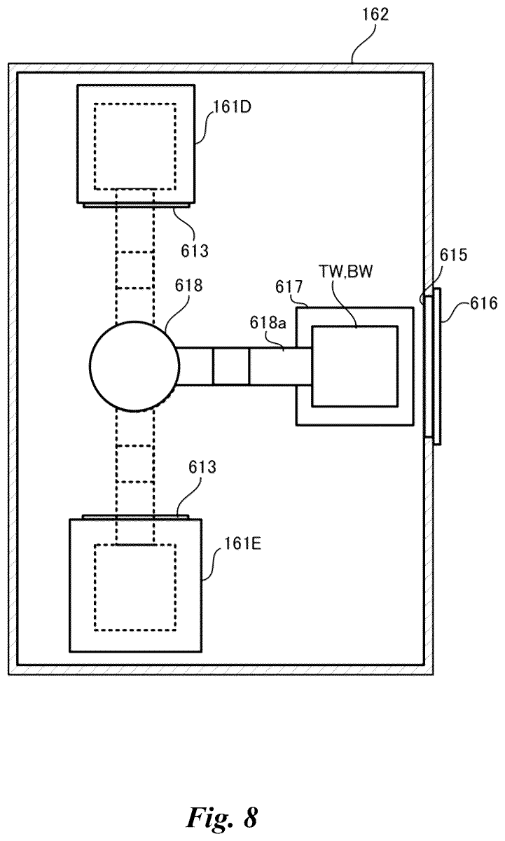

(5) In the above aspects, although two buffer units, the supply body buffer unit 160 for the component supply body TW and the mounting board buffer unit 170 for the mounting board BW, are used, one buffer unit may be used. For example, as illustrated in FIG. 8, a storage 161D for the component supply body TW and a storage 161E for the mounting board BW may be provided in one chamber 162, and the chamber 162 may be commonly used for the component supply body TW and the mounting board BW. In this case, as illustrated, one robot 618 may selectively house the workpiece in the storage 161D and the storage 161E. By this, the numbers of the chamber 162 and the transportation unit (robot 618) can be reduced, space, energy, and cost can be saved.

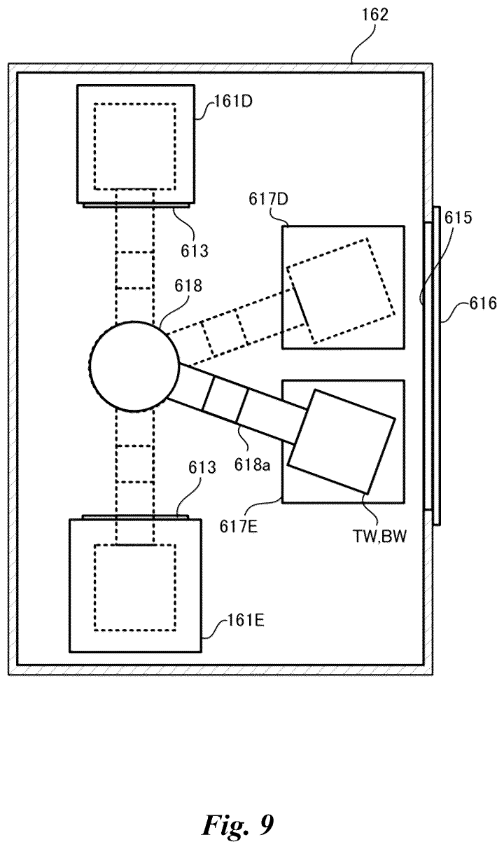

Furthermore, as illustrated in FIG. 9, a placement portion 617D for the component supply body TW and a placement portion 617E for the mounting board BW may be provided in the common chamber 162. By this, the workpiece can be carried into the chamber 162 without waiting even when the timing to carry the component supply body TW and the timing to carry the mounting board BW overlap. Furthermore, even when the chamber is accessed from outside to transport the workpiece relative to one of the placement portion (617D or 617E), the robot 618 can access to the other of the placement portion (617E or 617D), reducing takt time. Even in this case, the transportation unit inside the chamber 162 may be one robot 618. By this, the numbers of the chamber 162 and the transportation unit (robot 618) can be reduced, so that space, energy, and cost can be saved.

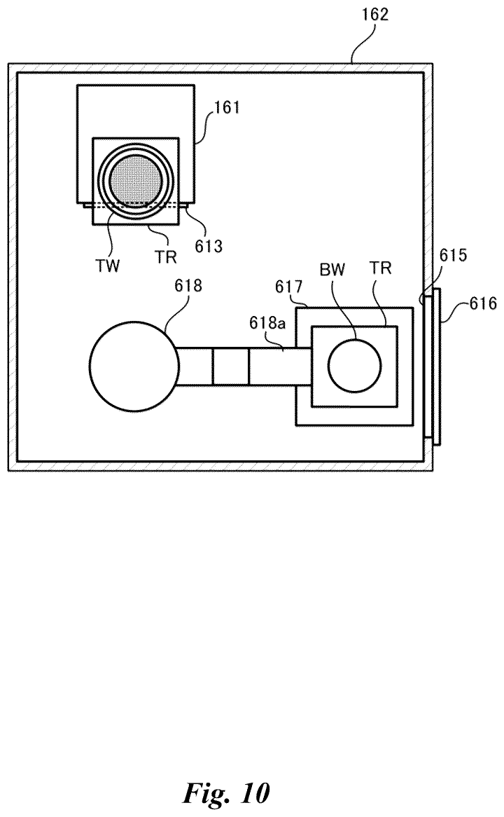

Furthermore, as illustrated in FIG. 10, when using the common chamber 162, one storage 161 may be commonly used for the component supply body TW and the mounting board BW. At this time, if the size between the component supply body TW and the mounting board BW is different, such as the component supply body TW formed by the ring R holding the tape T to which the electronic component E is attached and the mounting board BW that is the wafer, one storage 161 can be commonly used by using a tray TR for storing the workpiece to the storage 161. The tray TR has a size that can place both of the component supply body TW and the mounting board BW applied thereon. Since the storage 161 is configured to be capable of storing the tray TR which can load either of the component supply body TW and the mounting board BW, the storage 161 can be commonly used. Of course, one robot 618 may be used also in this case. By this, the chamber 162 can be made small and the number of the robot 618 can be reduced, so that space, energy, and cost can be saved.

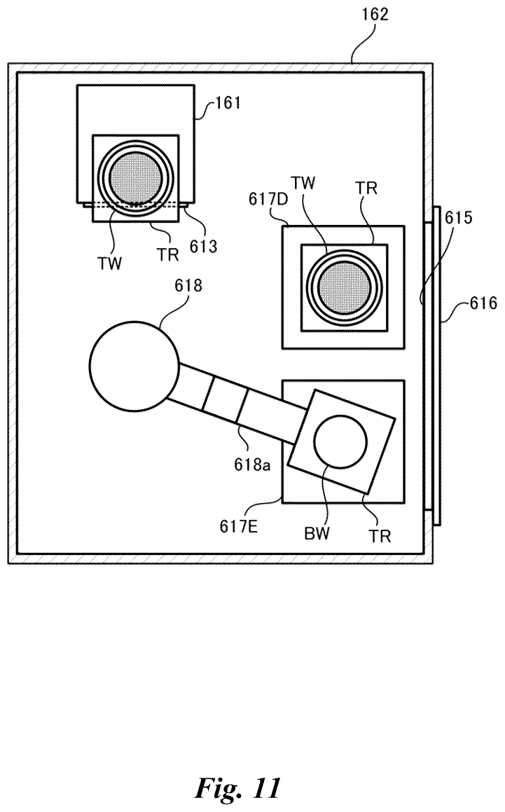

Note that, also in this case, as illustrated in FIG. 11, the placement portion 617D for the component supply body TW and the placement portion 617E for the mounting board BW may be provided in the common chamber 162. By this, the chamber 162 can be made small and the number of the robot 618 can be reduced, so that space, and energy, and cost can be saved. Furthermore, the workpiece can be carried into the chamber 162 without waiting even when the timing to carry the component supply body TW and the timing to carry the mounting board BW overlap. Furthermore, even when the chamber 162 is accessed from outside to transport the workpiece relative to one of the placement portion (617D or 617E), the transportation device that is the robot 618 can access to the other of the placement portion (617E or 617D) at the same time, reducing takt time.

### Other Embodiment

As above, although the modified examples of the embodiments and portions according to the present disclosure are described, these modified examples of the embodiments and portions are only presented as examples and are not intended to limit the scope of the claims. These new embodiments described above can be implemented in other various forms, and various omissions, replacements, modifications, combinations and changes may be made without departing from the abstract of the invention. These embodiments and modification thereof are included in the scope and abstract of the invention, and are included in the invention described in the scope of the claims.

### REFERENCE SIGN

1: mounting apparatus
11: base
12: chamber
13: load port
100: surface processing unit
110: supply body cleaning unit
111: cleaning room
111a: opening
111b: shutter
112: support
113: rotation mechanism
114: cup
115: supplying unit
115a: nozzle
115b: moving mechanism
120: mounting board cleaning unit
130: adjustment processing unit
131: irradiation device
140: positioning unit
150: alignment unit
160: supply body buffer unit
161, 161D, 161E: storage
161a: thermometer
161b: hygrometer
161c: pressure gauge
162: chamber
163: storage adjustment unit
163a: air supply path
163b: gas supply device
163c: flow meter
163d: filter
163e: valve
163f: exhaustion path
163g: valve
170: mounting board buffer unit
180: bonding unit
190: transportation unit
191: transportation robot
191a: robot hand
192: moving mechanism
200: control unit
210: memory
220: input unit
230: display
240: temperature-humidity control unit
250: preprocessing control unit
260: irradiation control unit
611: support
612: opening
613: storage-side shutter
613a: switch mechanism
614: irradiation device
615: opening
616: chamber-side shutter
616a: opening/closing mechanism
617, 617D, 617E: placement portion
618: robot
618a: robot hand
619: blowing device

What is claimed is:

1. A buffer apparatus comprising:
a storage that stores, after surface processing and/or cleaning process, a component supply body that is a workpiece which is a wafer diced into an electronic component attached on a tape attached to a ring, and a mounting board that is a workpiece on which the electronic component is mounted;
a chamber that houses the storage; and
a storage adjustment unit that adjusts temperature, humidity, and pressure of gas inside the storage independently from the chamber.

2. The buffer apparatus according to claim 1, wherein a blowing device that generates down flow of cleaning gas in the chamber is provided in the chamber.

3. The buffer apparatus according to claim 1, wherein:
an opening for carrying the workpiece in and out is provided to each of the chamber and the storage, a chamber-side shutter that opens when carrying the workpiece into and out from the chamber and closes when carrying the workpiece into and out from the storage is provided to the opening of the chamber, and
a storage-side shutter that opens when carrying the workpiece into and out from the storage and closes when carrying the workpiece into and out from the chamber is provided to the opening of the storage.

4. The buffer apparatus according to claim 1, wherein a placement portion to place the workpiece carried into the chamber, and a transportation unit that carries the workpiece placed on the placement portion into and out from the storage are provided inside the chamber.

5. The buffer apparatus according to claim 1, wherein an irradiation device that irradiates UV light on the workpiece is provided in the storage.

6. The buffer apparatus according to claim 1, wherein the storage stores the component supply body in which some of the electronic components are released and/or the mounting board on which the electronic component is mounted.

7. A preprocessing apparatus comprising:
a surface processing unit that processes a surface of the component supply body which is the wafer diced into the electronic component attached on the tape attached to the ring and/or the surface of a mounting board on which the electronic component is mounted;
a supply body cleaning unit that cleans the component supply body;
a mounting board cleaning unit that cleans the mounting board; and
the buffer apparatus according to claim 1.

8. A preprocessing apparatus comprising:
a surface processing unit that processes a surface of the component supply body which is the wafer diced into the electronic component attached on the tape attached to the ring and/or the surface of a mounting board on which the electronic component is mounted;
a supply body cleaning unit that cleans the component supply body;
a mounting board cleaning unit that cleans the mounting board; and
the buffer apparatus according to claim 3.

9. A mounting apparatus comprising:
a surface processing unit that processes a surface of the component supply body which is the wafer diced into the electronic component attached on the tape attached to the ring and/or the surface of a mounting board on which the electronic component is mounted;
a supply body cleaning unit that cleans the component supply body;
a mounting board cleaning unit that cleans the mounting board;
the buffer apparatus according to claim 1;
a bonding unit that mounts the electronic component on the mounting board;
a transportation unit that transports the component supply body and the mounting board; and
a preprocessing control unit that controls any of the surface processing unit, the supply body cleaning unit, and the mounting board cleaning unit to again clean or process the surface of the component supply body or the mounting board when predefined time has elapsed after the component supply body or the mounting board were housed in the buffer apparatus.

10. A mounting apparatus comprising:
a surface processing unit that processes a surface of the component supply body which is the wafer diced into the electronic component attached on the tape attached to the ring and/or the surface of a mounting board on which the electronic component is mounted;
a supply body cleaning unit that cleans the component supply body;
a mounting board cleaning unit that cleans the mounting board;
the buffer apparatus according to claim 3;
a bonding unit that mounts the electronic component on the mounting board;
a transportation unit that transports the component supply body and the mounting board; and
a preprocessing control unit that controls any of the surface processing unit, the supply body cleaning unit, and the mounting board cleaning unit to again clean or process the surface of the component supply body or the mounting board when predefined time has elapsed after the component supply body or the mounting board were housed in the buffer apparatus.

11. A preprocessing method comprising
a surface processing process of processing a surface of a component supply body which is a wafer diced into an electronic component attached on a tape attached to a ring and/or a surface of a mounting board on which the electronic component is mounted using a surface processing unit;
a supply body cleaning process of cleaning the component supply body using a supply body cleaning unit;
a mounting board cleaning process of cleaning the mounting board using a mounting board cleaning unit;
a supply body housing process of temporarily housing the component supply body in a storage provided in a chamber using a buffer apparatus for the component supply body, gas inside the storage being controlled independently from the chamber; and
a mounting board housing process of temporarily housing the mounting board in a storage provided in a chamber using a buffer apparatus for the mounting board, gas inside the storage being controlled independently from the chamber;
wherein:
in the supply body housing process, the surface processing process and/or the supply body cleaning process are performed again when predefined time elapses since the component supply body is housed, and
in the mounting board housing process, the surface processing process and/or the mounting board cleaning process are performed again when predefined time elapses since the mounting board is housed.

12. A mounting method comprising
a surface processing process of processing a surface of a component supply body which is a wafer diced into an electronic component attached on a tape attached to a ring and/or a surface of a mounting board on which the electronic component is mounted using a surface processing unit;
a supply body cleaning process of cleaning the component supply body using a supply body cleaning unit;
a mounting board cleaning process of cleaning the mounting board using a mounting board cleaning unit;
a supply body housing process of temporarily housing the component supply body in a storage provided in a chamber using a buffer apparatus for the component supply body, gas inside the storage being controlled independently from the chamber;
a mounting board housing process of temporarily housing the mounting board in a storage provided in a chamber using a buffer apparatus for the mounting board, gas inside the storage being controlled independently from the chamber; and
a bonding process of releasing the electronic component from the component supply body and mounting the electronic component on the mounting board using a bonding unit,
wherein:
in the supply body housing process, the surface processing process and/or the supply body cleaning process are performed again when predefined time elapses since the component supply body is housed, and
in the mounting board housing process, the surface processing process and/or the mounting board cleaning process are performed again when predefined time elapses since the mounting board is housed.
